(19) United States
(12) Patent Application Publication
(10) Pub. No.: US 2017/0099045 A1
(43) Pub. Date: Apr. 6, 2017

(54) SEMICONDUCTOR DEVICE AND METHOD FOR DRIVING THE SAME

(71) Applicant: SK hynix Inc., Gyeonggi-do (KR)

(72) Inventors: Yoon-Jae SHIN, Gyeonggi-do (KR); Kyeong-Tae KIM, Gyeonggi-do (KR)

(21) Appl. No.: 15/065,109

(22) Filed: Mar. 9, 2016

(30) Foreign Application Priority Data
Oct. 1, 2015 (KR) 10-2015-0138624

(51) Int. Cl. H03K 17/12; H03K 5/24

(52) U.S. Cl. CPC H03K 17/122; H03K 5/2472

(57) ABSTRACT

A semiconductor device includes: an initialization block suitable for initializing an internal voltage terminal based on a first voltage of a first voltage terminal; a feedback block suitable for generating a feedback voltage based on an internal voltage of the internal voltage terminal; a comparison block suitable for comparing the feedback voltage with a reference voltage to generate a comparison signal; a driving block suitable for driving the internal voltage terminal with a second voltage of a second voltage terminal in response to the comparison signal; and a leakage current prevention block suitable for selectively blocking a current path passing through the internal voltage terminal, the driving block and the second voltage terminal in response to a power-up signal corresponding to the first voltage.

### CROSS-REFERENCE TO RELATED APPLICATIONS

The present application claims priority of Korean Patent Application No. 10-2015-0138624, filed on Oct. 1, 2015, the disclosure of which is incorporated herein by reference in its entirety.

### BACKGROUND

1. Field

Exemplary embodiments of the present invention relate generally to a semiconductor design technology, and more particularly, to a semiconductor device for generating an internal voltage and a method for driving the semiconductor device.

2. Description of the Related Art

Semiconductor devices may generate an internal voltage required for internal operations based on an external voltage. For example, a memory device such as a Dynamic Random Access Memory (DRAM) may generate a core voltage VCORE supplied to a memory core region, a boosted voltage VPP used for driving word lines or overdriving, a reduced voltage VBB supplied as a back bias voltage of an NMOS transistor in a core region, and so on.

### SUMMARY

Exemplary embodiments of the present invention are directed to a semiconductor device for preventing a leakage current path occurring when different kinds of voltages are used and a method for driving the semiconductor device.

In accordance with an embodiment of the present invention, a semiconductor device includes: an initialization block suitable for initializing an internal voltage terminal based on a first voltage of a first voltage terminal; a feedback block suitable for generating a feedback voltage based on an internal voltage of the internal voltage terminal; a comparison block suitable for comparing the feedback voltage with a reference voltage to generate a comparison signal; a driving block suitable for driving the internal voltage terminal with a second voltage of a second voltage terminal in response to the comparison signal; and a leakage current prevention block suitable for selectively blocking a current path passing through the internal voltage terminal, the driving block and the second voltage terminal in response to a power-up signal corresponding to the first voltage.

A power-up section of the first voltage may be generated earlier than a power-up section of the second voltage.

The second voltage may be higher than the first voltage.

The leakage current prevention block may be formed between the driving block and the internal voltage terminal.

The leakage current prevention block may be formed between the second voltage terminal and the driving block.

The leakage current prevention block may block the current path during the power-up section of the first voltage and reflects on-resistance in the current path after passing the power-up section of the first voltage.

The comparison block may be enabled in response to a bias voltage.

The semiconductor device may further include: a power-up signal generation block suitable for generating the power-up signal based on the first voltage; and a control block suitable for generating the reference voltage and the bias voltage in response to the power-up signal.

In accordance with another embodiment of the present invention, a semiconductor device includes: an initialization block suitable for initializing an internal voltage terminal based on a first voltage of a first voltage terminal; a feedback block suitable for generating a feedback voltage based on an internal voltage of the internal voltage terminal; a comparison block suitable for comparing the feedback voltage with a reference voltage to generate a comparison signal; a driving block suitable for driving the internal voltage terminal with a second voltage of a second voltage terminal in response to the comparison signal; and a leakage current prevention block suitable for selectively blocking a current path passing through the first voltage terminal, the initialization block and the internal voltage terminal in response to power-up signal corresponding to the first voltage.

A power-up section of the first voltage may be generated earlier than a power-up section of the second voltage.

The second voltage may be higher than the first voltage.

The leakage current prevention block may be formed between the initialization block and the internal voltage terminal.

The leakage current prevention block may be formed between the first voltage terminal and the initialization block.

The leakage current prevention block may block the current path during the power-up section of the first voltage and reflects on-resistance in the current path after passing the power-up section of the first voltage.

The comparison block may be enabled in response to a bias voltage.

The semiconductor device may further include: a power-up signal generation block suitable for generating the power-up signal based on the first voltage; and a control block suitable for generating the reference voltage and the bias voltage in response to the power-up signal.

In accordance with another embodiment of the present invention, a method for driving a semiconductor device includes: supplying a first voltage; initializing an internal voltage based on the first voltage and blocking a current path between a first voltage terminal and an internal voltage terminal or a current path between a second voltage terminal and the internal voltage terminal during a power-up section of the first voltage; supplying a second voltage after passing the power-up section of the first voltage; and generating the internal voltage with the second voltage based on a reference voltage and a bias voltage.

The current path between the first voltage terminal and the internal voltage terminal or the current path between the second voltage terminal and the internal voltage terminal may be blocked by a leakage current prevention block during the power-up section, and on-resistance of the leakage current prevention block may be reflected in the current path between the first voltage terminal and the internal voltage terminal or the current path between the second voltage terminal and the internal voltage terminal after passing the power-up section.

The current path between the second voltage terminal and the internal voltage terminal may include a first current path between a driving block for driving the internal voltage terminal with the second voltage and the internal voltage terminal or a second current path between the second voltage terminal and the driving block, and the leakage current prevention block may be formed in the first current path or the second current path.

The current path between the first voltage terminal and the internal voltage terminal may include a third current path between an initialization block for initializing the internal voltage terminal with the first voltage and the internal voltage terminal or a fourth current path between the first voltage terminal and the initialization block, and the leakage current prevention block may be formed in the third current path or the fourth current path.

### BRIEF DESCRIPTION OF THE DRAWINGS

FIG. 1 is a block diagram illustrating an internal voltage generation block, according to a comparative example of the present invention.

FIG. 2 is a circuit diagram for the internal voltage generation block shown in FIG. 1.

FIG. 3 is a block diagram illustrating a semiconductor device having an internal voltage generation block, according to an embodiment of the present invention.

FIG. 4 is a block diagram illustrating an example of an internal voltage generation block, according to an embodiment of the present invention.

FIG. 5 is an example of a circuit diagram for the internal voltage generation block of FIG. 4, according to an embodiment of the present invention.

FIG. 6 is a diagram illustrating a method for driving a semiconductor device, according to an embodiment of the present invention.

FIG. 7 is a block diagram illustrating a semiconductor device having an internal voltage generation block, according to another embodiment of the present invention.

FIG. 8 is a block diagram illustrating an example of internal voltage generation block, according to another embodiment of the present invention.

FIG. 9 is an example of a circuit diagram for the internal voltage generation block of FIG. 8, according to another embodiment of the present invention.

FIG. 10 is a block diagram illustrating a semiconductor device having an internal voltage generator block, according to yet another embodiment of the present invention.

FIG. 11 is a block diagram illustrating an example of an internal voltage generation block, according to still other embodiment of the present invention.

FIG. 12 is an example of a circuit diagram illustrating an internal voltage generation block, according to yet another embodiment of the present invention.

FIG. 13 is a block diagram illustrating a semiconductor device, having an internal voltage generation block, according to the other embodiment of the present invention.

FIG. 14 is a block diagram illustrating an example of an internal voltage generation block, according to yet another embodiment of the present invention.

FIG. 15 is an example circuit diagram for the internal voltage generation block of FIG. 14, according to yet another embodiment of the present invention.

### DETAILED DESCRIPTION

Exemplary embodiments of the present invention are described below in more detail with reference to the accompanying drawings. These embodiments are provided so that this disclosure is thorough and complete and are not intended to limit the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “includes,” “comprising,” and/or “including” when used in this specification indicate the presence of stated features but do not preclude the presence or addition of one or more other features. As used herein, the term “and/or” indicates any and all combinations of one or more of the associated listed items. Throughout the disclosure, like reference numerals refer to like parts throughout the various figures and embodiments of the present invention.

Referring to FIG, an internal voltage generation block according to a comparative example of the present invention is provided. The internal voltage generation block may include an initialization unit 10, a feedback unit 20, comparison unit 30, and a driving unit 40 operatively coupled.

The initialization unit 10 may initialize a terminal of an internal voltage VLDO based on a power source voltage VDD. For example, the initialization unit 10 may initialize the terminal of the internal voltage VLDO according to a voltage level of the power source voltage VDD when the power source voltage VDD is powered up.

The feedback unit 20 may generate a feedback voltage VFDB which may be inputted to the comparison unit 30. The feedback voltage VFDB may be based on the internal voltage VLDO. For example, the feedback unit 20 may divide the internal voltage VLDO using a preset division ratio to generate the feedback voltage VFDB.

The comparison unit 30 may be enabled in response to a bias voltage VBIAS. The comparison unit 30 may compare a reference voltage VREF with the feedback voltage VFDB to generate a comparison signal VDIF which may be inputted to the driving unit 40. For example, the comparison unit 30 may include a differential amplifier. The comparison unit 30 may generate the comparison signal VDIF based on a boosted voltage VPP and a ground voltage VSS. The boosted voltage VPP may have a higher voltage level than the power source voltage VDD.

The driving unit 40 may drive the internal voltage VLDO terminal with the boosted voltage VPP in response to the comparison signal VDIF.

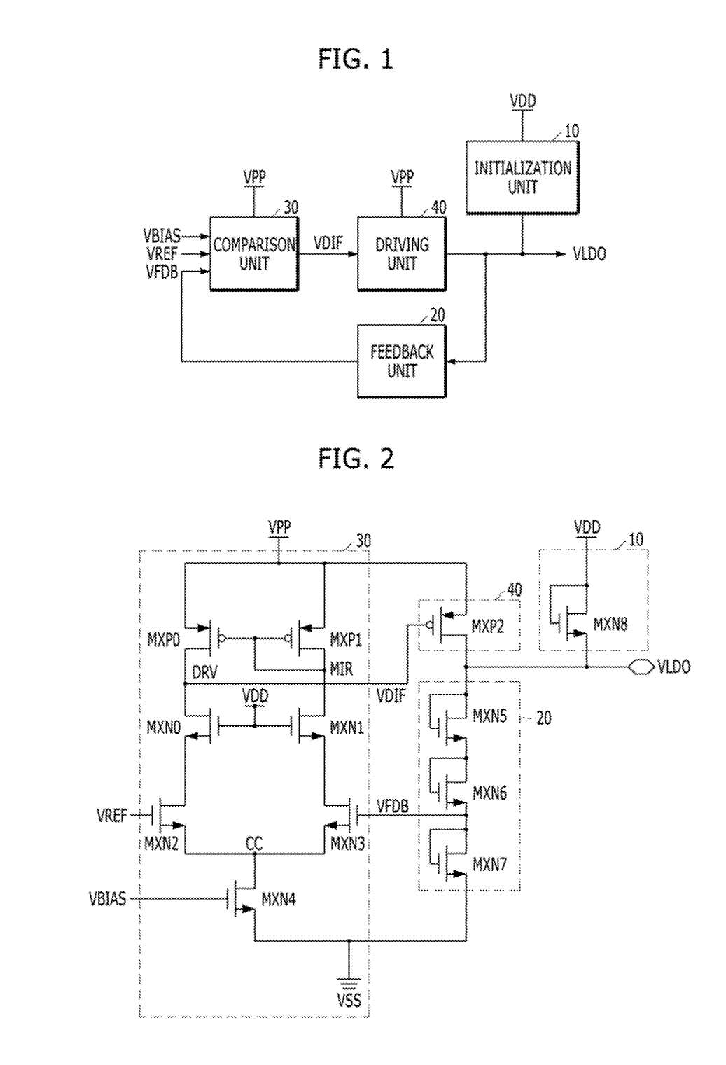

FIG. 2 is a circuit diagram illustrating the internal voltage generation block shown in FIG. 1.

Referring now to FIG. 2, the initialization unit 10 may include a ninth NMOS transistor MXN8. The ninth NMOS transistor MXN8 may have a drain and a gate coupled to a terminal of a power source voltage VDD and a source coupled to the internal voltage VLDO terminal.

The feedback unit 20 may include a sixth NMOS transistor MXN5, a seventh NMOS transistor MXN6, and an eighth NMOS transistor MXN7. The sixth NMOS transistor MXN5 may have a drain and a gate coupled to the internal voltage VLDO terminal and a source coupled to a drain of the seventh NMOS transistor MXN6. The seventh. NMOS transistor MXN6 may have the drain and a gate coupled to the source of the sixth NMOS transistor MXN5 and a source coupled to a terminal of a feedback voltage VFDB. The eighth NMOS transistor MXN7 may have a drain and a gate coupled to the feedback voltage VFDB terminal and a source coupled to a terminal of a ground voltage VSS.

The comparison unit 30 may include a first PMOS transistor MXP0, a second PMOS transistor MXP a first NMOS transistor MXN0, a second NMOS transistor MXN1, a third NMOS transistor MXN2, a fourth NMOS transistor MXN3, and a fifth NMOS transistor MXN4. The first PMOS transistor MXP0 may have a source coupled to a terminal of a boosted voltage VPP, a drain coupled to a first output terminal DRV and a gate coupled to a second output terminal MIR. The second PMOS transistor MXP1 may have a source coupled to the boosted voltage VPP terminal and a drain and a gate coupled to the second output terminal MIR. The first NMOS transistor MXN0 may have a drain coupled to the first output terminal DRV, a source coupled to a drain of the third NMOS transistor MXN2 and a gate coupled to the power source voltage VDD terminal. The second NMOS transistor MXN1 may have a drain coupled to the second output terminal MIR, a source coupled to a drain of the fourth NMOS transistor MXN3 and a gate coupled to the power source voltage VDD terminal. The third NMOS transistor MXN2 may have the drain coupled to the source of the first NMOS transistor MXN0, a source coupled to a common coupling terminal CC and a gate coupled to a terminal of a reference voltage VREF. The fourth NMOS transistor MXN3 may have the drain coupled to the source of the second NMOS transistor MXN1, a source coupled to the common coupling terminal CC and a gate coupled to the feedback, voltage VFDB terminal. The fifth NMOS transistor MXN4 may have a drain coupled to the common coupling terminal CC, a source coupled to a ground voltage VSS terminal and a gate coupled to a terminal of a bias voltage VBIAS.

The comparison signal VDIF may be outputted through the first output terminal DRV. The bias voltage VBIAS may be inputted as an enable signal for enabling the comparison unit 30.

The driving unit 40 may include a third PMOS transistor MXP2. The third PMOS transistor MXP2 may have a source coupled to the boosted voltage VPP terminal, a drain coupled to the internal voltage VLDO terminal and a gate coupled to the first output terminal DRV.

Hereinafter, an operation of the internal voltage generation block having the aforementioned structure will be described.

When the power source voltage VDD may be supplied, the initialization unit 10 may initialize the internal voltage VLDO terminal based on the power source voltage VDD. The internal voltage VLDO may have an initial voltage level corresponding to a voltage level VDD-VTH obtained by subtracting a threshold voltage VTH of the initialization unit 10 from the power source voltage VDD.

When the power source voltage VDD may be supplied, the reference and bias voltages VREF, VBIAS may be generated.

Subsequently, when the boosted voltage VPP may be supplied, the comparison unit 30 may compare the reference voltage VREF with the feedback voltage VFDB to generate the comparison signal VDIF. The comparison unit 30 may generate the comparison signal VDIF based on the boosted voltage VPP and the ground voltage VSS. The driving unit 40 may drive the internal voltage VLDO terminal with the boosted voltage VPP in response to the comparison signal VDIF.

Consequently, the internal voltage VLDO may be developed from the initial voltage level to a preset target level.

However, the internal voltage generation block having the aforementioned structure may have the following issue.

When the power source voltage VDD is supplied earlier than the boosted voltage VPP, a leakage current may flow from the power source voltage VDD terminal to the boosted voltage VPP terminal through the initialization unit 10, the internal voltage VLDO terminal and the driving unit 40. This may be because the initialization unit 10 may be turned on based on the power source voltage VDD, and the driving unit 40 may be turned on based on the comparison signal VDIF having an unknown voltage level before the boosted voltage VPP is supplied.

Since the reference and bias voltages VREF, VBIAS may be generated before the boosted voltage VPP is supplied, the comparison signal VDIF may have a ground voltage VSS level, not the unknown voltage level. Then, when the driving unit 40 may be fully turned on, the amount of the leakage current may increase.

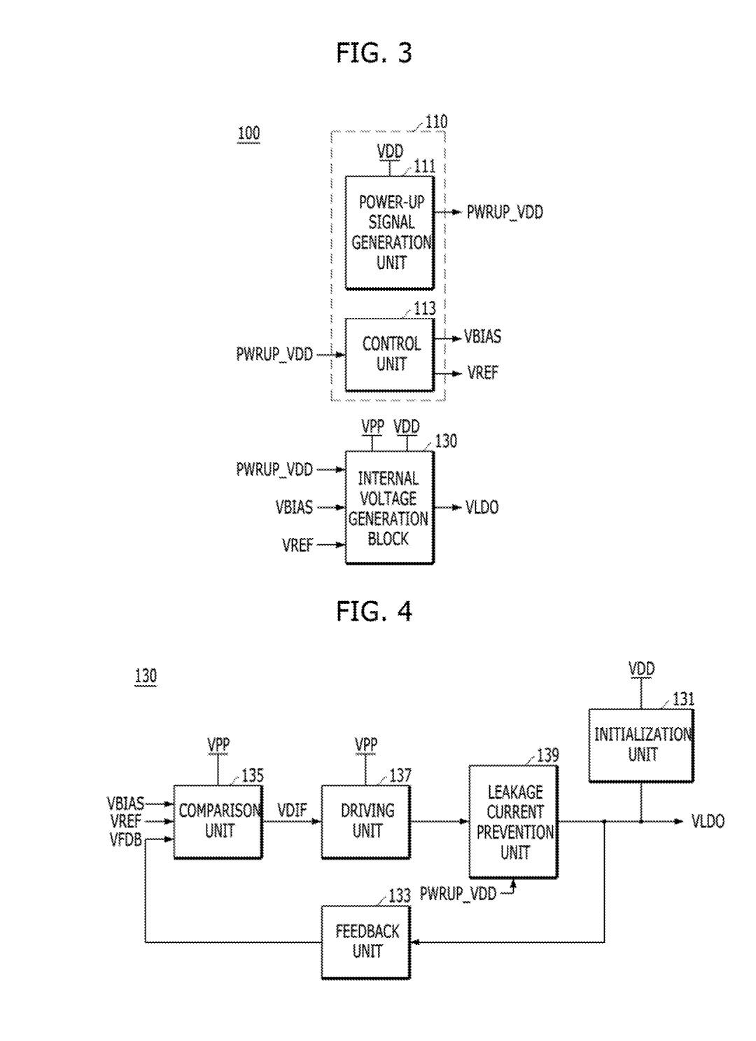

Referring now to FIG. 3, a semiconductor device 100, according to an embodiment of the present invention, may include an internal voltage control block 110, and an internal voltage generation block 130.

The internal voltage control block 110 may include a power-up signal generation unit 111 and a control unit 113. The power-up signal generation unit 111 may generate a power-up signal PWRUP_VDD corresponding to a power-up section of a power source voltage VDD. For example, the power-up signal generation unit 111 may generate the power-up signal PWRUP_VDD that may be developed when the power source voltage VDD may be powered up and may be transitioned into a low level logic when the power source voltage VDD reaches a preset voltage level lower than a target level of the power source voltage VDD. The control unit 113 may generate a bias voltage VBIAS and a reference voltage VREF based on the power-up signal PWRUP_VDD and supply the bias voltage VBIAS and the reference voltage VREF to the internal voltage generation block 130. For example, the control unit 113 may be enabled in response to the power-up signal PWRUP_VDD to generate the bias voltage VBIAS and then generate the reference voltage VREF based on the bias voltage VBIAS.

Since the power-up signal generation unit 111 and the control unit 113 are widely known to those skilled in the art, a detailed description thereof is omitted herein.

The internal voltage generation block 130 may employ different kinds of voltages as a source voltage. For example, the internal voltage generation block 130 may employ a boosted voltage VPP and the power source voltage VDD as the source voltage.

The power source voltage VDD may be supplied earlier than the boosted voltage VPP. For example, the power-up section of the power source voltage VDD may be generated earlier than a power-up section of the boosted voltage VPP. The power source voltage VDD and the boosted voltage VPP may be supplied from an external voltage generation circuit (not shown) of the semiconductor device 100. Alternatively, the power source voltage VDD may be supplied from the external voltage generation circuit, and the boosted voltage VPP may be supplied from an internal voltage generation circuit (not shown) of the semiconductor device 100.

Referring now to FIG. 4, an, internal voltage generation block 130, according to an embodiment of the present invention, may include an initialization unit 131, a feedback unit 133, a comparison unit 135, a driving unit 137, and a leakage current prevention unit 139 operatively coupled.

The initialization unit 131 may initialize a terminal of an internal voltage VLDO based on a power source voltage VDD. For example, the initialization unit 131 may initialize the internal voltage VLDO terminal according to a voltage level of the power source voltage VDD when the power source voltage VDD is powered up. The initialization unit 131 may have the same structure as the initialization unit 10 described above according to the comparative example.

The feedback unit 133 may generate a feedback voltage VFDB based on the internal voltage VLDO. For example, the feedback unit 133 may divide the internal voltage VLDO using a preset division ratio to generate the feedback voltage VFDB. The feedback unit 133 may have the same structure as the feedback unit 20 described above according to the comparative example.

The comparison unit 135 may be enabled in response to the bias voltage VBIAS. The comparison unit 135 may compare a reference voltage VREF with the feedback voltage VFDB to generate a comparison signal VDIF. For example, the comparison unit 135 may include a differential amplifier. The comparison unit 135 may generate the comparison signal VDIF based on a boosted voltage VPP and a ground voltage VSS. The boosted voltage VPP may have a higher voltage level than the power source voltage VDD. The comparison unit 135 may have the same structure as the comparison unit 30 described above according to the comparative example.

The driving unit 137 may drive the internal voltage VLDO terminal with the boosted voltage VPP in response to the comparison signal VDIF. The driving unit 137 may have the same structure as the driving unit 40 described above according to the comparative example.

The leakage current prevention unit 139 may selectively block a current path passing through the internal voltage VLDO terminal, the driving unit 137 and a terminal of the boosted voltage VPP in response to a power-up signal PWRUP_VDD. For example, the leakage current prevention unit 139 may selectively block a first current path between one side of the driving unit 137 and the internal voltage VLDO terminal. More particularly, the leakage current prevention unit 139 may block the first current path during a power-up section of the power source voltage VDD and reflect on-resistance in the first current path after passing the power-up section of the power source voltage VDD.

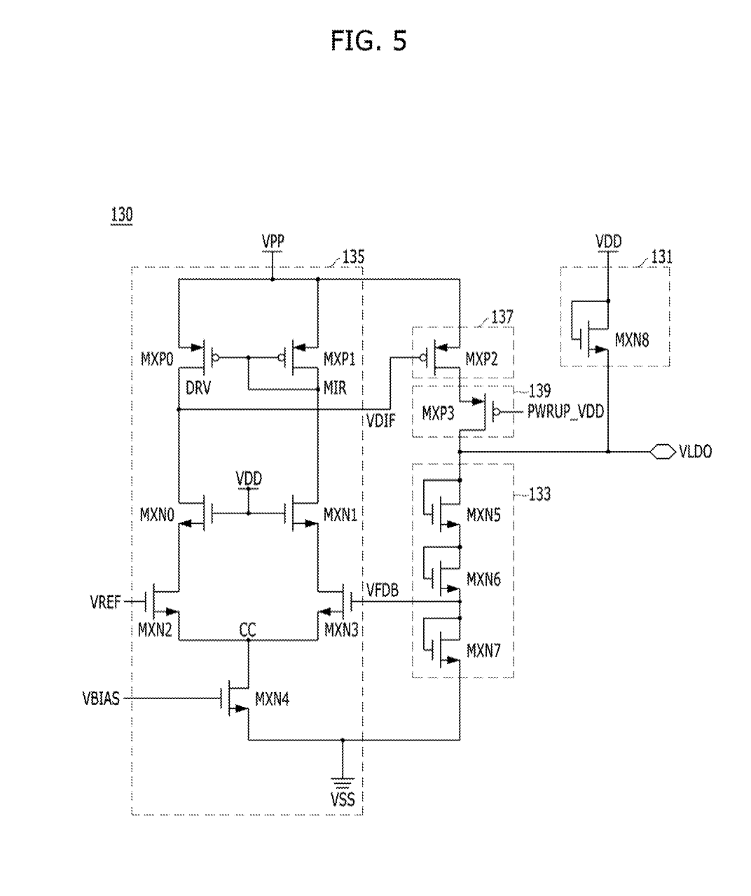

Referring now to FIG. 5 a circuit diagram for the internal voltage generation block 130 is provided, according to an embodiment of the present invention.

Specifically, the initialization unit 131 may include a ninth NMOS transistor MXN8. The ninth NMOS transistor MXN8 may have a drain and a gate coupled to a terminal of a power source voltage VDD and a source coupled to a terminal of an internal voltage VLDO.

The feedback unit 133 may include a sixth NMOS transistor MXN5 a seventh NMOS transistor MXN6, and an eighth NMOS transistor MXN7. The sixth NMOS transistor MXN5 may have a drain and a gate coupled to the internal voltage VLDO terminal and a source coupled to a drain of the seventh NMOS transistor MXN6. The seventh. NMOS transistor MXN6 may have the drain and a gate coupled to the source of the sixth NMOS transistor MXN5 and a source coupled to a terminal of a feedback voltage VFDB. The eighth NMOS transistor MXN7 may have a drain and a gate coupled to the feedback voltage VFDB terminal and a source coupled to a terminal of a ground voltage VSS.

The comparison unit 135 may include a first PMOS transistor MXP0, a second PMOS transistor MXP1, a first NMOS transistor MXN0, a second NMOS transistor MXN1, a third NMOS transistor MXN2, a fourth NMOS transistor MXN3, and a fifth NMOS transistor MXN4, The first PMOS transistor MXP0 may have a source coupled to a terminal of a boosted voltage VPP, a drain coupled to a first output terminal DRV and a gate coupled to a second output terminal MIR. The second PMOS transistor MXP1 may have a source coupled to the boosted voltage VPP terminal and a drain and a gate coupled to the second output terminal MIR. The first NMOS transistor MXN0 may have a drain coupled to the first output terminal DRV, a source coupled to a drain of the third NMOS transistor MXN2 and a gate coupled to the power source voltage VDD terminal. The second NMOS transistor MXN1 may have a drain coupled to the second output terminal MIR, a source coupled to a drain of the fourth NMOS transistor MXN3 and a gate coupled to the power source voltage VDD terminal the third NMOS transistor MXN2 may have the drain coupled to the source of the first NMOS transistor MXN0, a source coupled to a common coupling terminal CC and a gate coupled to a terminal of a reference voltage VREF. The fourth NMOS transistor MXN3 may have the drain coupled to the source of the second NMOS transistor MXN1, a source coupled to the common coupling terminal CC and a gate coupled to the feedback, voltage VFDB terminal. The fifth NMOS transistor MXN4 may have a drain coupled to the common coupling terminal CC, a source coupled to the ground voltage VSS terminal and a gate coupled to a terminal of a bias voltage VBIAS.

A comparison signal VDIF may be outputted through the first output terminal DRV. The bias voltage VBIAS may be inputted as an enable signal for enabling the comparison unit 135.

The driving unit 137 may include a third PMOS transistor MXP2. The third PMOS transistor MXP2 may have a source coupled to the boosted voltage VPP terminal, a drain coupled to one side of the leakage current prevention unit 139 and a gate coupled to the first output terminal DRV.

The leakage current prevention unit 139 may include a fourth PMOS transistor MXP3. The fourth PMOS transistor MXP3 may have a source coupled to the drain of the third PMOS transistor MXP2, a drain coupled to the internal voltage VLDO terminal and a gate coupled to an output terminal of a power-up signal PWRUP_VDD.

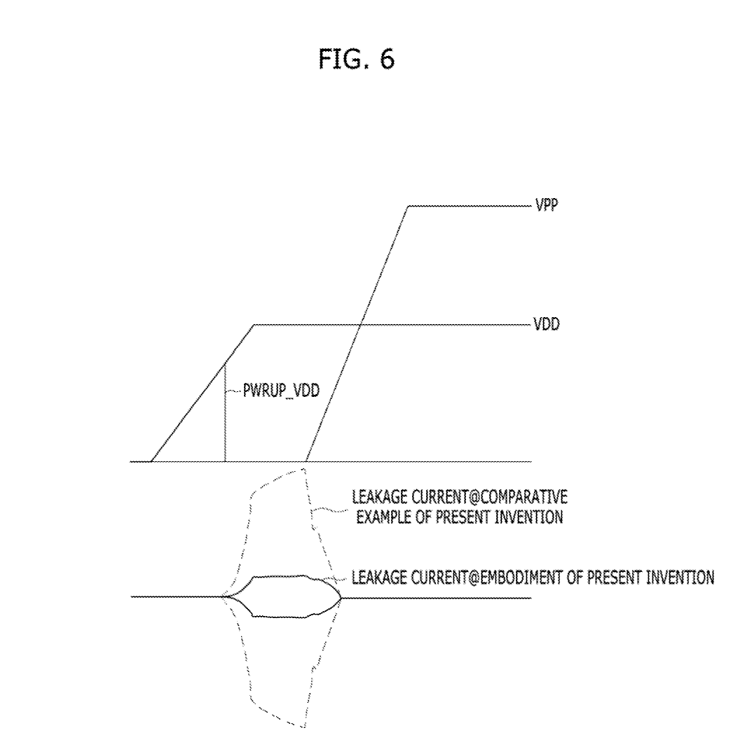

Hereinafter, an operation of the semiconductor device 100 having the aforementioned structure is described with reference to FIG. 6, according to an embodiment of the present invention.

Referring to FIG. 6, the method for driving a semiconductor device 100 may include supplying the power source voltage VDD, blocking the first current path during the power-up section of the power source voltage VDD, supplying the boosted voltage VPP after passing the power-up section of the power source voltage VDD, and generating the internal voltage VLDO with the boosted voltage VPP based on the reference and bias voltages VREF, VBIAS.

The supplying of the power source voltage VDD may mean that the power-up section of the power source voltage VDD may be earlier than the power-up section of the boosted voltage VPP. Each of the power-up sections may include a section where each voltage may be developed from a level of a ground voltage VSS to a preset target level. The power-up signal PWRUP_VDD may be developed when the power source voltage VDD may be powered up and may be transitioned into a low level logic when the power source voltage VDD may reach a preset voltage level lower than the target level.

In the blocking of the first current path during the power-up section of the power source voltage VDD, the internal voltage VLDO terminal may be initialized by the initialization unit 131, and the first current path may be blocked by the leakage current prevention unit 139. When the power source voltage VDD may be supplied, the initialization unit 131 may initialize the internal voltage VLDO terminal based on the power source voltage VDD. The leakage current prevention unit 139 may block the first current path while the internal voltage VLDO terminal is initialized. For example, the leakage current prevention unit 139 may block the first current path during the power-up section of the power source voltage VDD, based on the power-up signal PWRUP_VDD that is developed from the ground voltage VSS to the power source voltage VDD. Since this blocking may be performed before the boosted voltage VPP is supplied, the comparison signal VDIF may not be determined. Accordingly, although the driving unit 137 may be turned on, the first current path may be blocked by the leakage current prevention unit 139.

Supplying the boosted voltage VPP after passing the power-up section of the power source voltage VDD may be performed in a power-up section where the boosted voltage VPP is powered up. When the boosted voltage VPP is supplied, the comparison unit 135 may compare the feedback voltage VFDB with the reference voltage VREF based on the bias voltage VBIAS to generate the comparison signal VDIF. The comparison unit 135 may generate the comparison signal VDIF based on the boosted voltage VPP and the ground voltage VSS. The driving unit 137 may drive the internal voltage VLDO terminal with the boosted voltage VPP through the leakage current prevention unit 139 based on the comparison signal VDIF.

The method for driving the semiconductor device 100 according to an embodiment of the present invention may further include generating the reference and bias voltages VREF, VBIAS based on the power-up signal PWRUP_VDD of the power source voltage VDD.

Generation of the reference and bias voltages VREF, VBIAS may be carried out before supplying the boosted voltage VPP. For example, generation of the reference and bias voltages VREF, VBIAS may be carried out during a section (hereinafter referred to as a “leakage current increase section”) between the power-up section of the power source voltage VDD and the power-up section of the boosted voltage VPP. When the reference and bias voltages VREF, VBIAS are generated, the comparison unit 135 may perform a comparison operation. The leakage current prevention unit 139 may be turned on based on the power-up signal PWRUP-VDD having the low level logic to reflect the on-resistance in the first current path. During a leakage current increase section, when the reference and bias voltages VREF, VBIAS are generated, the comparison signal VDIF may have a logic level corresponding to the ground voltage VSS, and therefore, the driving unit 137 may be fully turned on. However, although a leakage current may occur through a path formed of the power source voltage VDD terminal, the internal voltage VLDO terminal and the boosted voltage VPP terminal, the leakage current may decrease due to the on-resistance.

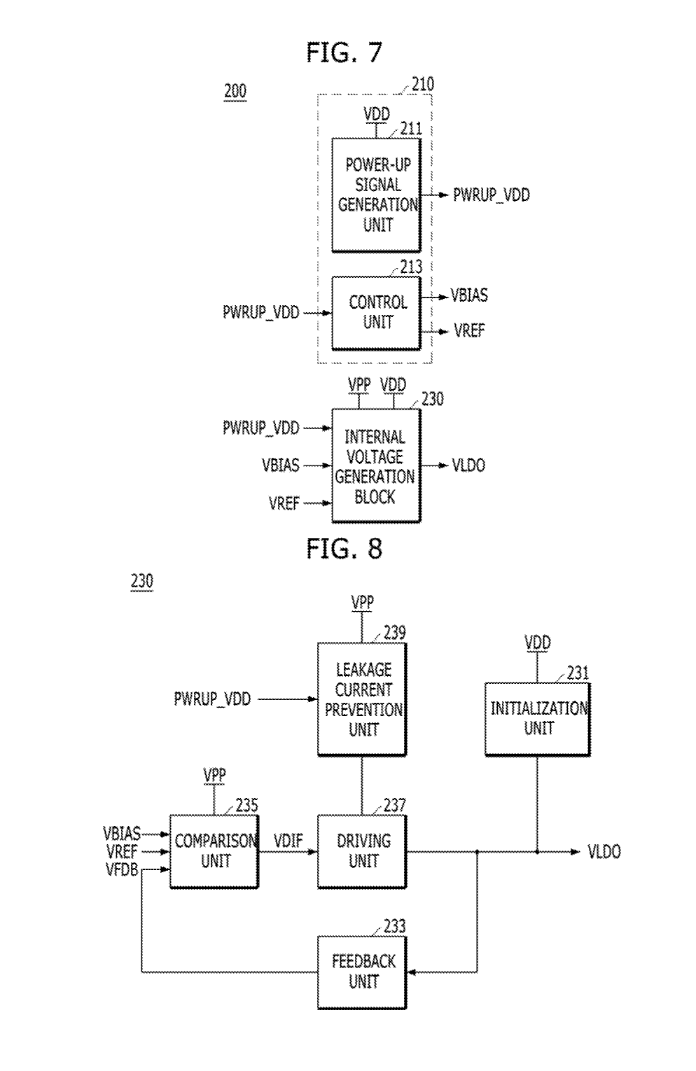

Referring to FIG. 7, a semiconductor device 200 according to another embodiment of the present invention may include an internal voltage control block 210, and an internal voltage generation block 230.

The internal voltage control block 210 may include a power-up signal generation unit 211, and a control unit 213. The power-up signal generation unit 211 may generate a power-up signal PWRUP_VDD corresponding to a power-up section of a power source voltage VDD. For example, the power-up signal generation unit 211 may generate the power-up signal PWRUP_VDD that may be developed when the power source voltage VDD is powered up and may be transitioned into a low level logic when the power source voltage VDD reaches a preset voltage level that is lower than a target level of the power source voltage VDD. The control unit 213 may generate a bias voltage VIAS and a reference voltage VREF based on the power-up signal PWRUP_VDD and supply the bias voltage VBIAS and the reference voltage VREF to the internal voltage generation block 230. For example, the control unit 213 may be enabled in response to the power-up signal PWRUP_VDD to generate the bias voltage VBIAS and then generate the reference voltage VREF based on the bias voltage VBIAS after generating the bias voltage VBIAS.

The power-up signal generation unit 211 and the control unit 213 may have the same structures as the power-up signal generation unit 111 and the control unit 113 described above.

The internal voltage generation block 230 may employ different kinds of voltages as a source voltage. For example, the internal voltage generation block 230 may employ a boosted voltage VPP and the power source voltage VDD as the source voltage.

The power source voltage VDD may be supplied earlier than the boosted voltage VPP. For example, the power-up section of the power source voltage VDD may be generated earlier than a power-up section of the boosted voltage VPP. The power source voltage VDD and the boosted voltage VPP may be supplied from an external voltage generation circuit (not shown) of the semiconductor device 200. Alternatively, the power source voltage VDD may be supplied from the external voltage generation circuit, and the boosted voltage VPP may be supplied from an internal voltage generation circuit (not shown) of the semiconductor device 100.

Referring now to FIG. 8, an internal voltage generation block 230 according to another embodiment of the present invention may include an initialization unit 231, a feedback unit 233, a comparison unit 235, a driving unit 237, and a leakage current prevention unit 239.

The initialization unit 231 may initialize a terminal of an internal voltage VLDO based on a power source voltage VDD. For example, the initialization unit 231 may initialize the internal voltage VLDO terminal according to a voltage level of the power source voltage VDD when the power source voltage VDD is powered up. The initialization unit 231 may have the same structure as the initialization unit 131 described above.

The feedback unit 233 may generate a feedback voltage VFDB based on the internal voltage VLDO. For example, the feedback unit 233 may divide the internal voltage VLDO using a preset division ratio to generate the feedback voltage VFDB. The feedback unit 233 may have the same structure as the feedback unit 133 described above.

The comparison unit 235 may be enabled in response to the bias voltage VBIAS. The comparison unit 235 may compare a reference voltage VREF with the feedback voltage VFDB to generate a comparison signal VDIF. For example, the comparison unit 235 may include a differential amplifier. The comparison unit 235 may generate the comparison signal VDIF based on a boosted voltage VPP and a ground voltage VSS. The boosted voltage VPP may have a higher voltage level than the power source voltage VDD. The comparison unit 235 may have the same structure as the comparison unit 135 described above.

The driving unit 237 may drive the internal voltage VLDO terminal with the boosted voltage VPP in response to the comparison signal VDIF. The driving unit 237 may have the same structure as the driving unit 137 described above.

The leakage current prevention unit 239 may selectively block a current path passing through the internal voltage VLDO terminal, the driving unit 237 and a terminal of the boosted voltage VPP in response to a power-up signal PWRUP_VDD. For example, the leakage current prevention unit 239 may block a second current path between the boosted voltage VPP terminal and one side of the driving unit 237 in response to the power-up signal PWRUP_VDD. More particularly, the leakage current prevention unit 239 may block the second current path during a power-up section of the power source voltage VDD and reflect on-resistance in the second current path after passing the power-up section of the power source voltage VDD.

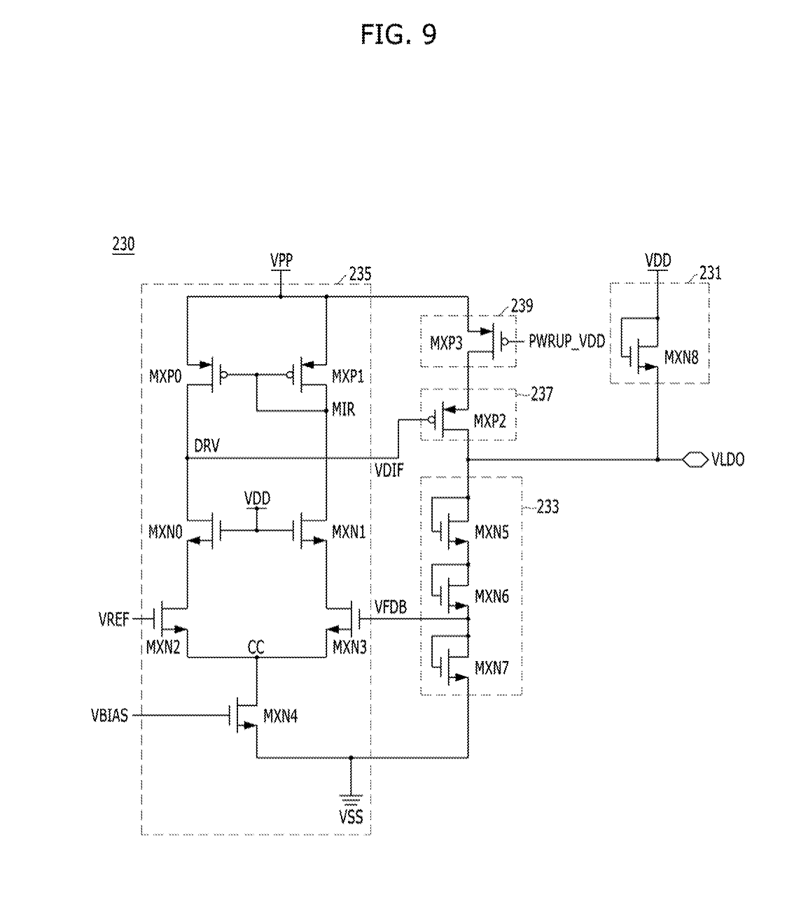

FIG. 9 is a circuit diagram illustrating an internal voltage generation block 230 according to another embodiment of the present invention.

Referring now to FIG. 9, the initialization unit 231 may include a ninth NMOS transistor MXN8. The ninth NMOS transistor MXN8 may have a drain and a gate coupled to a terminal of a power source voltage VDD and a source coupled to a terminal of an internal voltage VLDO.

The feedback unit 233 may include a sixth NMOS transistor MXN5, a seventh NMOS transistor MXN6, and an eighth NMOS transistor MXN7. The sixth NMOS transistor MXN5 may have a drain and a gate coupled to the internal voltage VLDO terminal and a source coupled to a drain of the seventh NMOS transistor MXN6. The seventh NMOS transistor MXN6 may have the drain and a gate coupled to the source of the sixth NMOS transistor MXN5 and a source coupled to a terminal of a feedback voltage VFDB. The eighth NMOS transistor MXN7 may have a drain and a gate coupled to the feedback voltage VFDB terminal and a source coupled to a terminal of a ground voltage VSS.

The comparison unit 235 may include a first PMOS transistor MXP0, a second PMOS transistor MXP1, a first NMOS transistor MXN0, a second NMOS transistor MXN1, a third NMOS transistor MXN2, a fourth NMOS transistor MXN3, and a fifth NMOS transistor MXN4. The first PMOS transistor MXP0 may have a source coupled to a terminal of a boosted voltage VPP, a drain coupled to a first output terminal DRV and a gate coupled to a second output terminal MIR. The second PMOS transistor MXP1 may have, a source coupled to the boosted voltage VPP terminal and a drain and a gate coupled to the second output terminal MIR. The first NMOS transistor MXN0 may have a drain coupled to the first output terminal DRV, a source coupled to a drain of the third NMOS transistor MXN2 and a gate coupled to the power source voltage VDD terminal. The second NMOS transistor MXN1 may have a drain coupled to the second output terminal MIR, a source coupled to a drain of the fourth NMOS transistor MXN3 and a gate coupled to the power source voltage VDD terminal. The third NMOS transistor MXN2 may have the drain coupled to the source of the first NMOS transistor MXN0, a source coupled to a common coupling terminal CC and a gate coupled to a terminal of a reference voltage VREF. The fourth NMOS transistor MXN3 may have the drain coupled to the source of the second NMOS transistor MXN1, a source coupled to the common coupling terminal CC and a gate coupled to the feedback voltage VFDB terminal. The fifth NMOS transistor MXN4 may have a drain coupled to the common coupling terminal CC, a source coupled to the ground voltage VSS terminal and a gate coupled to a terminal of a bias voltage VBIAS.

A comparison signal VDIF may be outputted through the first output terminal DRV. The bias voltage VBIAS may be inputted as an enable signal for enabling the comparison unit 235.

The driving unit 237 may include a third PMOS transistor MXP2. The third PMOS transistor MXP2 may have a source coupled to one side of the leakage current prevention unit 239, a drain coupled to the internal voltage VLDO terminal and a gate coupled to the first output terminal DRV.

The leakage current prevention unit 239 may include a fourth PMOS transistor MXP3. The fourth PMOS transistor MXP3 may have a source coupled to the boosted voltage VPP terminal, a drain coupled to the source of the third PMOS transistor MXP2 and a gate coupled to an output terminal of a power-up signal PWRUP_VDD.

Hereinafter, a method for driving the semiconductor device 200 having the aforementioned structure is described

The method for driving the semiconductor device 200 may be similar to the method for driving the semiconductor device 100 (refer to FIG. 6). For example, the method for driving the semiconductor device 200 may include supplying the power source voltage VDD, blocking the second current path during the power-up section of the power source voltage VDD, supplying the boosted voltage VPP after passing the power-up section of the power source voltage VDD, and generating the internal voltage VLDO with the boosted voltage VPP based on the reference and bias voltages VREF, VBIAS. Among the above-described methods, a different method from the method for driving the semiconductor device 100 is described below.

In the blocking of the second current path during the power-up section of the power source voltage VDD, the internal voltage VLDO terminal may be initialized by the initialization unit 231, and the second current path may be blocked by the leakage current prevention unit 239. When the power source voltage VDD may be supplied, the initialization unit 231 may initialize the internal voltage VLDO terminal based on the power source voltage VDD. The internal voltage VLDO may have an initial voltage level corresponding to a voltage level VDD-VTH obtained by subtracting a threshold voltage VTH of the initialization unit 231 from the power source voltage VDD. The leakage current prevention unit 239 may block the second current path while the internal voltage VLDO terminal is initialized. For example, the leakage current prevention unit 239 may block the second current path during the power-up section of the power source voltage VDD based on the power-up signal PWRUP_VDD that is developed from the ground voltage VSS to the power source voltage VDD. Since this blocking may be performed before the boosted voltage VPP is supplied, the comparison signal VDIF may not be determined. Accordingly, although the driving unit 237 may be turned on, the second current path may be blocked by the leakage current prevention unit 239.

The method for driving the semiconductor device 200 according to another embodiment of the present invention may further include generating the reference and bias voltages VREF, VBIAS based on the power-up signal PWRUP_VDD of the power source voltage VDD.

Generation of the reference and bias voltages VREF, VBIAS may be carried out before supplying the boosted voltage VPP. For example, Generation of the reference and bias voltages VREF, VBIAS may be carried out during a section (hereinafter referred to as a “leakage current increase section”) between the power-up section of the power source voltage VDD and the power-up section of the boosted voltage VPP. When the reference and bias voltages VREF, VBIAS may be generated, the comparison unit 235 may perform a comparison operation. The leakage current prevention unit 239 may be turned on based on the power-up signal PWRUP_VDD having the low level logic to reflect the on-resistance in the second current path. During the leakage current increase section, when the reference and bias voltages VREF, VBIAS may be generated, the comparison signal VDIF may have a logic level corresponding to the ground voltage VSS, and therefore, the driving unit 337 may be fully turned on. However, although a leakage current may occur from the current path passing through the power source voltage VDD terminal, the internal voltage VLDO terminal and the boosted voltage VPP terminal, the leakage current may decrease due to the on-resistance.

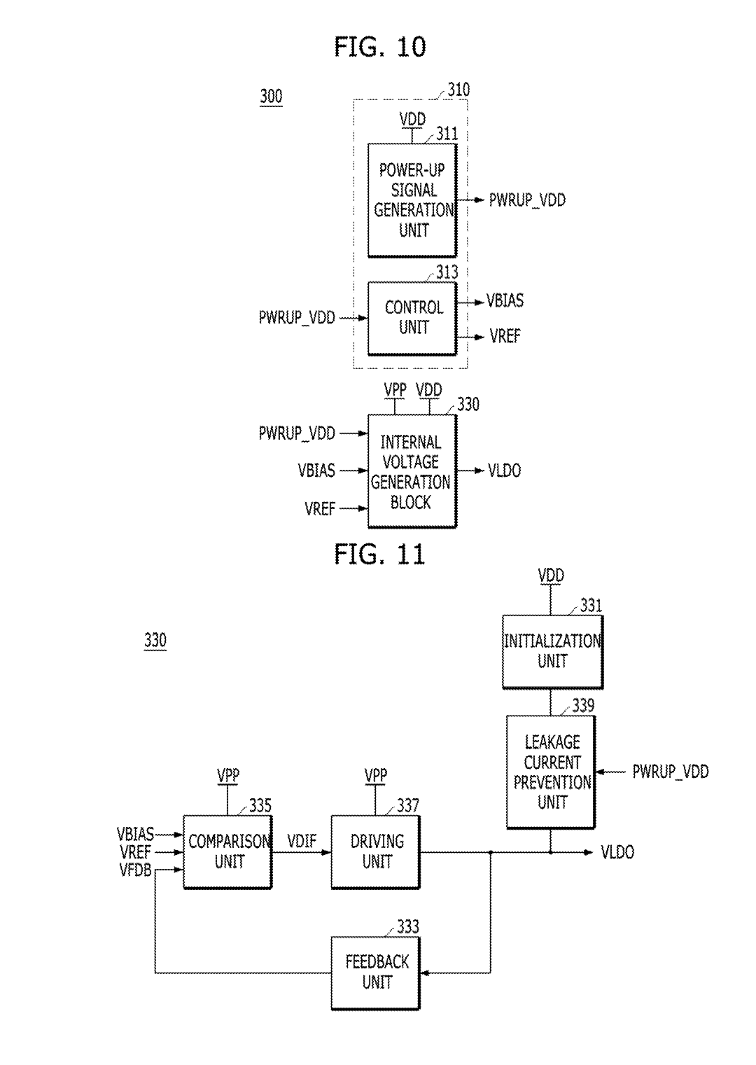

Referring to FIG. 10, a semiconductor device 300 according to still other embodiment of the present invention may include an internal voltage control block 310, and an internal voltage generation block 330.

The internal voltage control block 310 may include a power-up signal generation unit 311, and a control unit 313. The power-up signal generation unit 311 may generate a power-up signal PWRUP_VDD corresponding to a power-up section of a power source voltage VDD. For example, the power-up signal generation unit 311 may generate the power-up signal PWRUP_VDD that may be developed when the power source voltage VDD may be powered up and may be transitioned into a low level logic when the power source voltage VDD may reach a preset voltage level lower than a target level of the power source voltage VDD. The control unit 313 may generate a bias voltage VBIAS and a reference voltage VREF based on the power-up signal PWRUP_VDD and supply the bias voltage VBIAS and the reference voltage VREF to the internal voltage generation block 330. For example, the control unit 313 may be enabled in response to the power-up signal PWRUP_VDD to generate the bias voltage VBIAS and then generate the reference voltage VREF based on the bias voltage VBIAS.

The power-up signal generation unit 311 and the control unit 313 may have the same structure as the power-up signal generation unit 111 and the control unit 113 described above.

The internal voltage generation block 330 may employ different kinds of voltages as a source voltage. For example, the internal voltage generation block 330 may employ a boosted voltage VPP and the power source voltage VDD as the source voltage.

The power source voltage VDD may be supplied earlier than the boosted voltage VPP. For example the power-up section of the power source voltage VDD may be generated earlier than a power-up section of the boosted voltage VPP. The power source voltage VDD and the boosted voltage VPP may be supplied from an external voltage generation circuit (not shown) of the semiconductor device 300. Alternatively, the power source voltage VDD may be supplied from the external voltage generation circuit, and the boosted voltage VPP may be supplied from an internal voltage generation circuit (not shown) of the semiconductor device 300.

Referring now to FIG. 11, an internal voltage generation block 330 according to still other embodiment of the present invention may include an initialization unit 331, a feedback unit 333, a comparison unit 335, a driving unit 337, and a leakage current prevention unit 339.

The initialization unit 331 may initialize a terminal of an internal voltage VLDO based on a power source voltage VDD. Since the initialization unit 331 may initialize the internal voltage VLDO terminal through the leakage current prevention unit 339, the internal voltage VLDO terminal may be initialized after the power source voltage VDD is powered up. The initialization unit 331 may have the same structure as the initialization unit 131 described above.

The feedback unit 333 may generate a feedback voltage VFDB based on the internal voltage VLDO. For example, the feedback unit 333 may divide the internal voltage VLDO using a preset division ratio to generate the feedback voltage VFDB. The feedback unit 333 may have the same structure as the feedback unit 133 described above.

The comparison unit 335 may be enabled in response to the bias voltage VBIAS. The comparison unit 335 may compare a reference voltage VREF with the feedback voltage VFDB to generate a comparison signal VDIF. For example, the comparison unit 335 may include a differential amplifier. The comparison unit 335 may generate the comparison signal VDIF based on a boosted voltage VPP and a ground voltage VSS. The boosted voltage VPP may have a higher voltage level than the power source voltage VDD. The comparison unit 335 may have the same structure as the comparison unit 135 described above.

The driving unit 337 may drive the internal voltage VLDO terminal with the boosted voltage VPP in response to the comparison signal VDIF. The driving unit 337 may have the same structure as the driving unit 137 described above.

The leakage current prevention unit 333 may selectively block a current path passing through a terminal of the power source voltage VDD, the initialization unit 331 and the internal voltage VLDO terminal in response to a power-up signal PWRUP_VDD. For example, the leakage current prevention unit 339 may block a third current path between one side of the initialization unit 331 and the internal voltage VLDO terminal. More particularly, the leakage current prevention unit 339 may block the third current path during a power-up section of the power source voltage VDD and reflect on-resistance in the third current path after passing the power-up section of the power source voltage VDD.

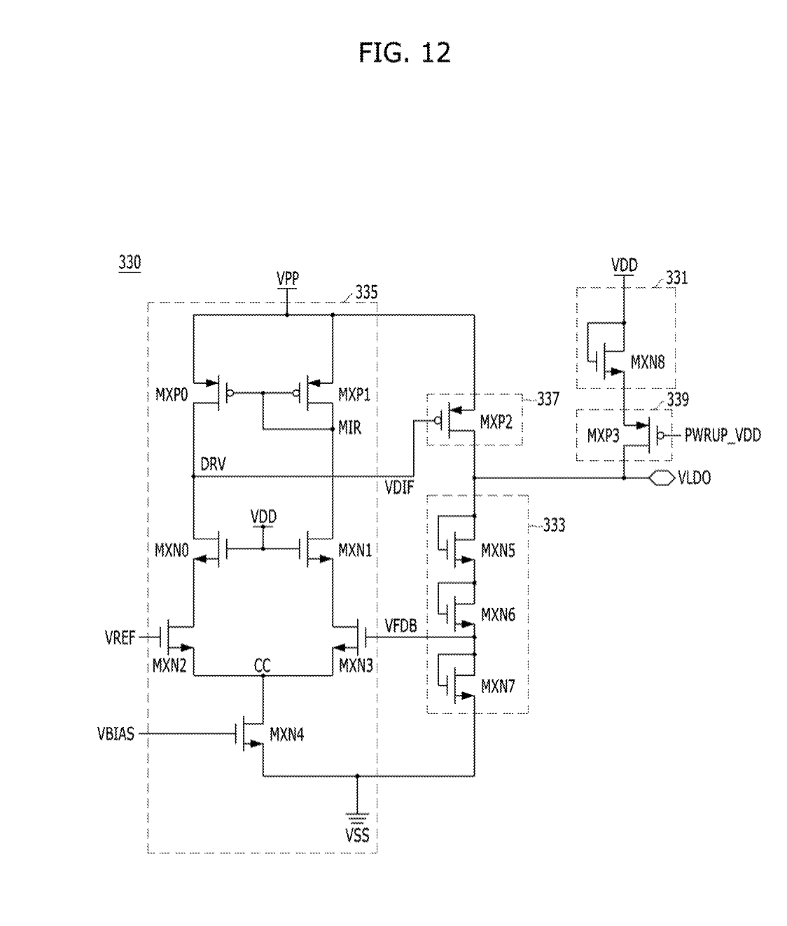

Referring to FIG. 12 a circuit diagram of the internal voltage generation block 330 is provided, according to still another embodiment of the present invention.

Specifically, the initialization unit 331 may include a ninth NMOS transistor MXN8. The ninth NMOS transistor MXN8 may have a drain and a gate coupled to a terminal of a power source voltage VDD and a source coupled to one side of the leakage current prevention unit 339.

The feedback unit 333 may include sixth, seventh and eighth NMOS transistors, MXN5, MXN6 and MXN7 respectively. The sixth NMOS transistor MXN5 may have a drain and a gate coupled to a terminal of the internal voltage VLDO and a source coupled to a drain of the seventh NMOS transistor MXN6. The seventh NMOS transistor MXN6 may have the drain and a gate coupled to the source of the sixth NMOS transistor MXN5 and a source coupled to a terminal of a feedback voltage VFDB. The eighth NMOS transistor MXN7 may have a drain and a gate coupled to the feedback voltage VFDB terminal and a source coupled to a terminal of a ground voltage VSS.

The comparison unit 335 may include first and second PMOS transistors MXP0, MXP1, and first, second, third, fourth and fifth NMOS transistors MXN0, MXN1, MXN2, MXN3, and MXN4, respectively. The first PMOS transistor MXP0 may have a source coupled to a terminal of a boosted voltage VPP, a drain coupled to a first output terminal DRV and a gate coupled to a second output terminal MIR. The second PMOS transistor MXP1 may have a source coupled to the boosted voltage VPP terminal and a drain and a gate coupled to the second output terminal MIR. The first NMOS transistor MXN0 may have a drain coupled to the first output terminal DRV, a source coupled to a drain of the third NMOS transistor MXN2 and a gate coupled to the power source voltage VDD terminal. The second NMOS transistor MXN1 may have a drain coupled to the second output terminal MIR, a source coupled to a drain of the fourth NMOS transistor MXN3 and a gate coupled to the power source voltage VDD terminal. The third NMOS transistor MXN2 may have the drain coupled to the source of the first NMOS transistor MXN0, a source coupled to a common coupling terminal CC and a gate coupled to a reference voltage VREF terminal. The fourth NMOS transistor MXN3 may have the drain coupled to the source of the second NMOS transistor MXN1, a source coupled to the common coupling terminal CC and a gate coupled to the feedback voltage VFDB terminal. The fifth NMOS transistor MXN4 may have a drain coupled to the common coupling terminal CC, a source coupled to the ground voltage VSS terminal and a gate coupled to a terminal of a bias voltage VBIAS.

A comparison signal VDIF may be outputted through the first output terminal DRV. The bias voltage VBIAS may be inputted as an enable signal for enabling the comparison unit 335.

The driving unit 337 may include a third PMOS transistor MXP2. The third PMOS transistor MXP2 may have a source coupled to the boosted voltage VPP terminal, a drain coupled to the internal voltage VLDO terminal and a gate coupled to the first output terminal DRV.

The leakage current prevention unit 339 may include a fourth PMOS transistor MXP3. The fourth PMOS transistor MXP3 may have a source coupled to the source of the ninth NMOS transistor MXN8, a drain coupled to the internal voltage VLDO terminal and a gate coupled to an output terminal of a power-up signal PWRUP_VDD.

Hereinafter, a method for driving the semiconductor device 300 having the aforementioned structure is described.

The method for driving the semiconductor device 300 may be similar to the method for driving the semiconductor device 100 (refer to FIG. 6). For example, the method for driving the semiconductor device 300 may include supplying the power source voltage VDD, blocking the third current path during the power-up section of the power source voltage VDD, supplying the boosted voltage VPP after passing the power-up section of the power source voltage VDD, and generating the internal voltage VLDO with the boosted voltage VPP based on the reference and bias voltages VREF, VBIAS.

In an embodiment, the third current path may be blocked by the leakage current prevention unit 339. For example, when the power source voltage VDD is supplied the leakage current prevention unit 339 may block the third current path during the power-up section of the power source voltage VDD based on the power-up signal PWRUP_VDD that is developed from the ground voltage VSS to the power source voltage VDD. Since this blocking may be performed before supplying the boosted voltage VPP, the comparison signal VDIF may not be determined. Accordingly, although the driving unit 337 may be turned on, the third current path may be blocked by the leakage current prevention unit 339.

In an embodiment, in supplying the boosted voltage VPP after passing the power-up section of the power source voltage VDD, the internal voltage VLDO terminal may be initialized first, before supplying the boosted voltage VPP. Since the initialization unit 331 may initialize the internal voltage VLDO terminal through the leakage current prevention unit 339, the leakage current prevention unit 339 may be turned on, and then the initialization unit 331 may initialize the internal voltage VLDO terminal. For example, the power-up signal PWRUP_VDD may be developed from the ground voltage VSS to the power source voltage VDD and transitioned into a ground voltage VSS level, then one side of the initialization unit 331 and the internal voltage VLDO terminal may be electrically coupled via the leakage current prevention unit 339, and the internal voltage VLDO terminal may be initialized.

A method for driving the semiconductor device 300 according to an embodiment of the present invention may further include generating the reference and bias voltages VREF, VBIAS based on the power-up signal PWRUP_VDD of the power source voltage VDD.

Generation of the reference and bias voltages VREF, VBIAS may be carried out before supplying of the boosted voltage VPP. For example, generation of the reference and bias voltages VREF, VBIAS may be carried out during a section between the power-up section of the power source voltage VDD and the power-up section of the boosted voltage VPP, hereinafter referred to also as a “leakage current increase section”. When the reference and bias voltages VREF, VBIAS are generated, the comparison unit 335 may perform a comparison operation. The leakage current prevention unit 339 may be turned on based on the power-up signal PWRUP_VDD having a low level logic to reflect the on-resistance in the third current path. During the leakage current increase section, when the reference and bias voltages VREF, VBIAS may be generated, the comparison signal VDIF may have a logic level corresponding to the ground voltage VSS, and therefore, the driving unit 337 may be fully turned on. However, although a leakage current may occur from a current passing through a path formed of the power source voltage VDD terminal, the internal voltage VLDO terminal and the boosted voltage VPP terminal, the leakage current may decrease due to the on-resistance.

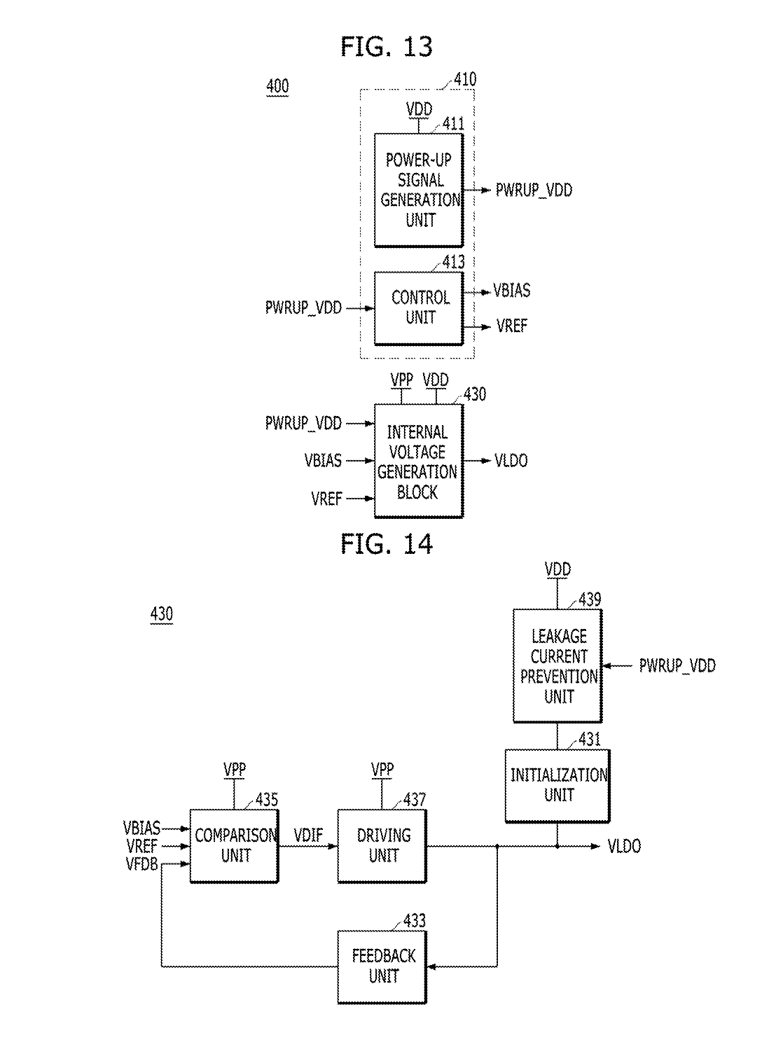

Referring to FIG. 13, a semiconductor device 400, according to the yet another embodiment of the present invention, may include an internal voltage control block 410, and an internal voltage generation block 430.

The internal voltage control block 410 may include a power-up signal generation unit 411 and a control unit 413. The power-up signal generation unit 411 may generate a power-up signal PWRUP_VDD corresponding to a power-up section of a power source voltage VDD. For example, the power-up signal generation unit 411 may generate the power-up signal PWRUP_VDD developed when the power source voltage VDD may be powered up and may be transitioned into a low level logic when the power source voltage VDD reaches a preset voltage level lower than a target level of the power source voltage VDD. The control unit 413 may generate a bias voltage VBIAS and a reference voltage VREF based on the power-up signal PWRUP_VDD and supply the bias voltage VBIAS and the reference voltage VREF to the internal voltage generation block 430. For example, the control unit 413 may be enabled in response to the power-up signal PWRUP_VDD to generate the bias voltage VBIAS and then generate the reference voltage VREF based on the bias voltage VBIAS.

The power-up signal generation unit 411 and the control unit 413 may have the same structures as the power-up signal generation unit 111 and the control unit 113 described above.

The internal voltage generation block 430 may employ different kinds of voltages as a source voltage. For example the internal voltage generation block 430 may employ a boosted voltage VPP and the power source voltage VDD.

The power source voltage VDD may be supplied earlier than the boosted voltage VPP. For example, the power-up section of the power source voltage VDD may be generated earlier than a power-up section of the boosted voltage VPP. The power source voltage VDD and the boosted voltage VPP may be supplied from an external voltage generation circuit (not shown) of the semiconductor device 400. Alternatively, the power source voltage VDD may be supplied from the external voltage generation circuit, and the boosted voltage VPP may be supplied from an internal voltage generation circuit (not shown) of the semiconductor device 400.

Referring now to FIG. 14, an internal voltage generation block 430, according to yet another embodiment of the present invention, may include an initialization unit 431, a feedback unit 433, a comparison unit 435, a driving unit 437, and a leakage current prevention unit 439.

The initialization unit 431 may initialize a terminal of an internal voltage VLDO based on a power source voltage VDD. Since the initialization unit 431 may initialize the internal voltage VLDO terminal through the leakage current prevention unit 439, the internal voltage VLDO terminal may be initialized after the power source voltage VDD is powered up. The initialization unit 431 may have the same structure as the initialization unit 131 described above.

The feedback unit 433 may generate a feedback voltage VFDB based on the internal voltage VLDO. For example, the feedback unit 433 may divide the internal voltage VLDO using a preset division ratio to generate the feedback voltage VFDB. The feedback unit 433 may have the same structure as the feedback unit 133 described above.

The comparison unit 435 may be enabled in response to the bias voltage VBIAS. The comparison unit 435 may compare a reference voltage VREF with the feedback voltage VFDB for generating a comparison signal VDIF. For example, the comparison unit 435 may include a differential amplifier. The comparison unit 435 may generate the comparison signal VDIF based on a boosted voltage VPP and a ground voltage VSS. The boosted voltage VPP may have a higher voltage level than the power source voltage VDD. The comparison unit 435 may have the same structure as the comparison unit 135 described above.

The driving unit 437 may drive the internal voltage VLDO terminal with the boosted voltage VPP in response to the comparison signal VDIF. The driving unit 437 may have the same structure as the driving unit 137 described above,

The leakage current prevention unit 439 may selectively block a current path passing through a terminal of a power source voltage VDD, the initialization unit 431 and the internal voltage VLDO terminal in response to a power-up signal PWRUP_VDD. For example, the leakage current prevention unit 439 may block a fourth current path between the power source voltage VDD terminal and one side of the initialization unit 431. More particularly, the leakage current prevention unit 439 may block the fourth current path during a power-up section of the power source voltage VDD and reflect on-resistance in the fourth current path after passing the power-up section of the power source voltage VDD.

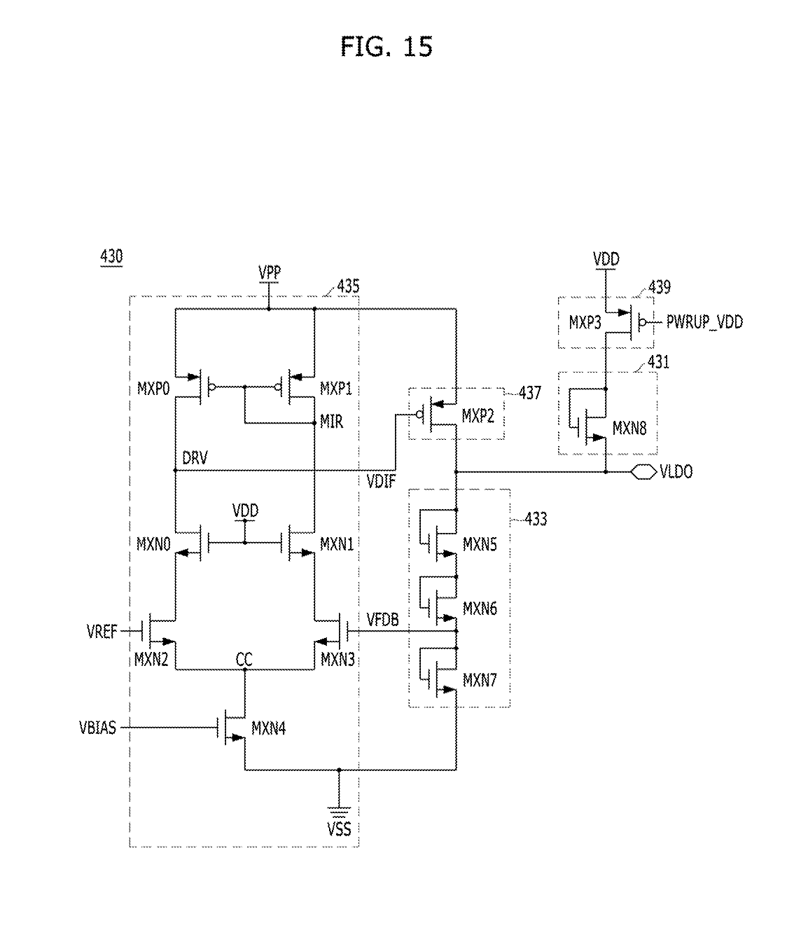

FIG. 15 is a circuit diagram illustrating the internal voltage generation block 430, according to yet another embodiment of the present invention.

Referring now to FIG. 15, the initialization unit 431 may include a ninth NMOS transistor MXN8. The ninth NMOS transistor MXN8 may have a drain and a gate coupled to one side of the leakage current prevention unit 439 and a source coupled to a terminal of an internal voltage VLDO.

The feedback unit 433 may include a sixth, seventh and an eighth NMOS transistors MXN5, MXN6, and MXN7, respectively. The sixth NMOS transistor MXN5 may have a drain and a gate coupled to the internal voltage VLDO terminal and a source coupled to a drain of the seventh NMOS transistor MXN6. The seventh NMOS transistor MXN6 may have the drain and a gate coupled to the source of the sixth NMOS transistor MXN5 and a source coupled to a terminal of a feedback voltage VFDB. The eighth NMOS transistor MXN7 may have a drain and a gate coupled to the feedback voltage VFDB terminal and a source coupled to a terminal of a ground voltage VSS.

The comparison unit 435 may include first and second PMOS transistors MXP0, MXP1, first, second, third, fourth and fifth NMOS transistors MXN0, MXN1, MXN2, NMOS, MXN3, and MXN4, respectively. The first PMOS transistor MXP0 may have a source coupled to a terminal of a boosted voltage VPP, a drain coupled to a first output terminal DRV and a gate coupled to a second output terminal MIR. The second PMOS transistor MXP1 may have a source coupled to the boosted voltage VPP terminal and a drain and a gate coupled to the second output terminal MIR. The first NMOS transistor MXN0 may have a drain coupled to the first output terminal DRV, a source coupled to a drain of the third NMOS transistor MXN2 and a gate coupled to a terminal of a power source voltage VDD. The second NMOS transistor MXN1 may have a drain coupled to the second output terminal MIR, a source coupled to a drain of the fourth NMOS transistor MXN3 and a gate coupled to the power source voltage VDD terminal. The third NMOS transistor MXN2 may have the drain coupled to the source of the first NMOS transistor MXN0, a source coupled to a common coupling terminal CC and a gate coupled to a terminal of a reference voltage VREF. The fourth NMOS transistor MXN3 may have the drain coupled to the source of the second NMOS transistor MXN1, a source coupled to the common coupling terminal CC and a gate coupled to the feedback voltage VFDB terminal. The fifth NMOS transistor MXN4 may have a drain coupled to the common coupling terminal CC, a source coupled to the ground voltage VSS terminal and a gate coupled to a terminal of a bias voltage VBIAS.

A comparison signal VDIF may be outputted through the first output terminal DRV. The bias voltage VBIAS may be inputted as an enable signal for enabling the comparison unit 435.

The driving unit 437 may include a third PMOS transistor MXP2. The third PMOS transistor MXP2 may have a source coupled to the boosted voltage VPP terminal, a drain coupled to the internal voltage VLDO terminal and a gate coupled to the first output terminal DRV.

The leakage current prevention unit 439 may include a fourth PMOS transistor MXP3. The fourth PMOS transistor MXP3 may have a source coupled to the power source voltage VDD terminal, a drain coupled to the drain of the ninth NMOS transistor MXN8 and a gate coupled to an output terminal of a power-up signal PWRUP_VDD.

Hereinafter, a method for driving the semiconductor device 400 having the aforementioned structure is described.

The method for driving the semiconductor device 400 may be similar to the method for driving the semiconductor device 100 (refer to FIG. 6). For example, the method for driving the semiconductor device 400 may include supplying the power source voltage VDD, blocking the fourth current path during the power-up section of the power source voltage VDD, supplying the boosted voltage VPP after passing the power-up section of the power source voltage VDD, and generating the internal voltage VLDO with the boosted voltage VPP based on the reference and bias voltages VREF, VBIAS.

In an embodiment, the fourth current path may be blocked by the leakage current prevention unit 439. For example, when the power source voltage VDD is supplied, the leakage current prevention unit 439 may block the fourth current path during the power-up section of the power source voltage VDD based on the power-up signal PWRUP_VDD developed from the ground voltage VSS to the power source voltage VDD. Since this blocking may be performed before the boosted voltage VPP is supplied, the comparison signal VDIF may not be determined. Accordingly, although the driving unit 437 may be turned on, the fourth current path may be blocked by the leakage current prevention unit 439.

In an embodiment, supplying of the boosted voltage VPP after passing the power-up section of the power source voltage VDD, may include initializing first the internal voltage VLDO terminal, before supplying the boosted voltage VPP. Since the initialization unit 431 may initialize the internal voltage VLDO terminal through the leakage current prevention unit 439, the leakage current prevention unit 439 may be turned on, and then the initialization unit 431 may initialize the internal voltage VLDO terminal. For example, the power-up signal PWRUP_VDD may be developed from the ground voltage VSS to the power source voltage VDD and may be transitioned into a ground voltage VSS level. Then the power source voltage VDD terminal and one side of the initialization unit 431 may be electrically coupled via the leakage current prevention unit 439, and the internal voltage VLDO terminal may be initialized.

The method for driving the semiconductor device 400 according to an embodiment of the present invention may further include generating the reference and bias voltages VREF, VBIAS based on the power-up signal PWRUP_VDD of the power source voltage VDD.

Generation of the reference and bias voltages VREF, VBIAS may be carried out before supplying the boosted voltage VPP. For example, generation of the reference and bias voltages VREF, VBIAS may be carried out during a section between the power-up section of the power source voltage VDD and the power-up section of the boosted voltage VPP. When the reference and bias voltages VREF, VBIAS are generated, the comparison unit 435 may perform a comparison operation. The leakage current prevention unit 439 may be turned on based on the power-up signal PWRUP_VDD having the low level logic to reflect the resistance in the fourth current path. During the leakage current increase section, when the reference and bias voltages VREF, VBIAS are generated, the comparison signal VDIF may have a logic level corresponding to the ground voltage VSS, and therefore, the driving unit 437 may be fully turned on. However, although a leakage current may occur from the path formed of the power source voltage VDD terminal, the internal voltage VLDO terminal and the boosted voltage VPP terminal, the leakage current may decrease due to the on-resistance.

In accordance with the embodiments of the present invention, a leakage current occurring in a current path may decrease by blocking the current path formed over the power source voltage VDD terminal for initializing the internal voltage VLDO terminal, the internal voltage VLDO terminal and the boosted voltage VPP terminal or by reflecting the on-resistance in the current path.

In accordance with embodiments of the present invention, performance of a semiconductor device may be improved by preventing a leakage current path occurring when different kinds of voltages are employed.

While the present invention has been described with respect to specific embodiments, the embodiments are not intended to be restrictive. Further, it is noted that the present invention may be achieved in various ways through substitution, change, and modification, by those skilled in the art without departing from the scope of the present invention as defined by the following claims.

What is claimed is:

1. A semiconductor device, comprising:
an initialization block suitable for initializing an internal voltage terminal based on a first voltage of a first voltage terminal;
a feedback block suitable for generating a feedback voltage based on an internal voltage of the internal voltage terminal;
a comparison block suitable for comparing the feedback voltage with a reference voltage to generate a comparison signal;
a driving block suitable for driving the internal voltage terminal with a second voltage of a second voltage terminal in response to the comparison signal; and
a leakage current prevention block suitable for selectively blocking a current path passing through the internal voltage terminal, the driving block and the second voltage terminal in response to a power-up signal corresponding to the first voltage.

2. The semiconductor device of claim 1, wherein a power-up section of the first voltage is generated earlier than a power-up section of the second voltage.

3. The semiconductor device of claim 2, wherein the second voltage is higher than the first voltage.

4. The semiconductor device of claim 1, wherein the leakage current prevention block is formed between the driving block and the internal voltage terminal.

5. The semiconductor device of claim 1, wherein the leakage current prevention block is formed between the second voltage terminal and the driving block.

6. The semiconductor device of claim 1, wherein the leakage current prevention block blocks the current path during the power-up section of the first voltage and reflects on-resistance in the current path after passing the power-up section of the first voltage.

7. The semiconductor device of claim 1, wherein the comparison block is enabled in response to a bias voltage.

8. The semiconductor device of claim 7, further comprising:
a power-up signal generation block suitable for generating the power-up signal based on the first voltage; and
a control block suitable for generating the reference voltage and the bias voltage in response to the power-up signal.

9. A semiconductor device, comprising:
an initialization block suitable for initializing an internal voltage terminal based on a first voltage of a first voltage terminal;
a feedback block suitable for generating feedback voltage based on an internal voltage of the internal voltage terminal;
a comparison block suitable for comparing the feedback voltage with a reference voltage to generate a comparison signal;
a driving block suitable for driving the internal voltage terminal with a second voltage of a second voltage terminal in response to the comparison signal; and
a leakage current prevention block suitable for selectively blocking a current path passing through the first voltage terminal, the initialization block and the internal voltage terminal in response to a power-up signal corresponding to the first voltage.

10. The semiconductor device of claim 9, wherein a power-up section of the first voltage is generated earlier than a power-up section of the second voltage.

11. The semiconductor device of claim 10, wherein the second voltage is higher than the first voltage.

12. The semiconductor device of claim 9, wherein the leakage current prevention block is formed between the initialization block and the internal voltage terminal.

13. The semiconductor device of claim herein the leakage current prevention block is formed between the first voltage terminal and the initialization block.

14. The semiconductor device of claim 9, wherein the leakage current prevention block blocks the current path during the power-up section of the first voltage and reflects on-resistance in the current path after passing the power-up section of the first voltage.

15. The semiconductor device of claim 9, wherein the comparison block is enabled in response to a bias voltage.

16. The semiconductor device of claim 15, further comprising.
a power-up signal generation block suitable for generating the power-up signal based on the first voltage; and
a control block suitable for generating the reference voltage and the bias voltage in response to the power-up signal.

17. A method for driving a semiconductor device, comprising:
supplying a first voltage;
initializing an internal voltage based on the first voltage and blocking a current path between a first voltage terminal and an internal voltage terminal or a current path between a second voltage terminal and the internal voltage terminal during a power-up section of the first voltage;
supplying a second voltage after passing the power-up section of the first voltage; and
generating the internal voltage with the second voltage based on a reference voltage and a bias voltage.

18. The method of claim 17, wherein the current path between the first voltage terminal and the internal voltage terminal or the current path between the second voltage terminal and the internal voltage terminal are blocked by a leakage current prevention block during the power-up section, and
on-resistance of the leakage current prevention block is reflected in the current path between the first voltage terminal and the internal voltage terminal or the current path between the second voltage terminal and the internal voltage terminal after passing the power-up section.

19. The method of claim 18, wherein the current path between the second voltage terminal and the internal voltage terminal includes a first current path between a driving block for driving the internal voltage terminal with the second voltage and the internal voltage terminal or a second current path between the second voltage terminal and the driving block, and
the leakage current prevention block is formed in the first current path or the second current path.

20. The method of claim 18, wherein the current path between the first voltage terminal and the internal voltage terminal includes a third current path between an initialization block for initializing the internal voltage terminal with the first voltage and the internal voltage terminal or a fourth current path between the first voltage terminal and the initialization block, and
the leakage current prevention block is formed in the third current path or the fourth current path.
